(19) United States
(12) Patent Application Publication
(10) Pub. No.: US 2025/0312780 A1
(43) Pub. Date: Oct. 9, 2025

(54) LIQUID-PHASE ALLOY CATALYST, METHOD OF MANUFACTURING SAME AND TWO-DIMENSIONAL CHALCOGENIDE THIN FILM COMPRISING THERMODYNAMICALLY INDUCED GRAIN BOUNDARY IN MONOLAYER CRYSTAL USING SAME

(71) Applicant: POSTECH RESEARCH AND BUSINESS DEVELOPMENT FOUNDATION, Pohang-si (KR)

(72) Inventors: Cheol-Joo KIM, Pohang-si (KR); Min-Yeong CHOI, Pohang-si (KR); Si-Young CHOI, Pohang-si (KR); Chang-Won CHOI, Pohang-si (KR)

(73) Assignee: POSTECH RESEARCH AND BUSINESS DEVELOPMENT FOUNDATION, Pohang-si (KR)

(21) Appl. No.: 19/098,337

(22) Filed: Apr. 2, 2025

(30) Foreign Application Priority Data
Apr. 4, 2024 (KR) 10-2024-0046093

(51) Int. Cl. B01J 35/27; B01J 23/28; B01J 23/30; B01J 37/02; B01J 37/08; C01B 19/04; C01G 39/06; C01G 41/00; C03C 17/22; C09K 11/68; C09K 11/88; H10D 62/80

(52) U.S. Cl. CPC B01J 35/27; B01J 23/28; B01J 23/30; B01J 37/0238; B01J 37/08; C01B 19/04; C01G 39/06; C01G 41/00; C03C 17/22; C09K 11/681; C09K 11/881; C01P 2002/82; C01P 2002/85; C01P 2004/02; C01P 2004/04; C01P 2006/60; C03C 2217/288; C03C 2217/289; C03C 2217/70; C03C 2218/11; C03C 2218/15; H10D 62/883

(57) ABSTRACT

Disclosed is a liquid-phase alloy catalyst, method of manufacturing same and two-dimensional chalcogenide thin film comprising thermodynamically induced grain boundary in monolayer crystal using same. In detail, a liquid-phase alloy catalyst for synthesizing a two-dimensional chalcogenide thin film, the liquid-phase alloy catalyst comprising an alloy including an alkali metal, a transition metal and an oxygen atom. The present disclosure has the effect of stably providing a uniform chemical environment through an independent liquid alloy catalyst in a chemically non-uniform synthetic environment.

### CROSS REFERENCE TO RELATED APPLICATION

The present application claims priority to Korean Patent Application No. 10-2024-0046093, filed on Apr. 4, 2024, the entire contents of which are incorporated herein for all purposes by this reference.

### BACKGROUND OF THE DISCLOSURE

### 1. Field of the Disclosure

The present disclosure relates to a liquid-phase alloy catalyst, method of manufacturing same and two-dimensional chalcogenide thin film comprising thermodynamically induced grain boundary in monolayer crystal using same.

### 2. Description of the Related Art

In general, the thin film synthesis based on chemical vapor deposition, a conventional technology currently in use, proceeds with the synthesis of a specific thin film through surface diffusion of solid-phase atoms adsorbed by a vapor-phase precursor. This is performed through a dynamic mechanism-based behavior, resulting in a polycrystalline thin film formed by grain boundaries with a thermodynamically unstable atomic structure. This results in the formation of polycrystalline thin films composed of grain boundaries with different structural forms rather than the same atomic structure within the same material. In addition, the current thin film synthesis is performed through a reaction at a high temperature (around 800° C.) for solid-phase atomic decomposition and sufficient surface diffusion of the decomposed particles from the vapor-phase precursor injected into the reactor.

However, the synthesis of polycrystalline thin films using the conventional technology has two major problems. The first is that grain boundary with different atomic structures are formed even within the same thin film due to the dynamic mechanism-based behavior. This is caused by the fabrication of a non-uniform chemical environment inside the reactor due to the mixing of gas-phase precursors injected in the chemical vapor deposition method. As a result, polycrystalline thin films formed within a non-uniform chemical environment have local differences in the atomic structures within the grain boundaries. As a result, the physical properties are not expressed in a uniform form, and when ultimately applied to devices, etc., this acts as a cause of performance degradation. Second, high process temperatures are required during the thin film synthesis for smooth surface diffusion of solid-phase atoms. This is a problem that can ultimately cause damage to other components within the device when integrating two-dimensional materials into various devices and forming on different surfaces. Currently, there is no method for synthesizing the grain boundaries with atomic-level accuracy. In addition, this dynamic synthesis technique has difficulty in developing and synthesizing new materials formed through a metastable environment due to the heterogeneous and unstable chemical environment within the reactor.

Therefore, there is a need to develop a method for manufacturing a polycrystalline thin film with grain boundary having a thermodynamically stable atomic structure.

### SUMMARY OF THE DISCLOSURE

The purpose of the present disclosure is to solve the above problems, and to form the atomic structure constituting theoretically the grain boundary into one thermodynamically stable form by utilizing the behavior based on the thermodynamic mechanism.

In addition, another purpose of the present disclosure is to enable the synthesis of a thin film even at a relatively low temperature (500° C.) by adding an alkali metal capable of providing a catalytic effect on the synthesis of existing two-dimensional materials to a liquid-phase alloy introduced as a reaction intermediate.

In addition, another purpose of the present disclosure is to provide an environment in which the synthesis of new materials is possible by uniformly providing a metastable chemical environment.

One aspect of the present disclosure is to provide a liquid-phase alloy catalyst for synthesizing a two-dimensional chalcogenide thin film, the liquid-phase alloy catalyst comprising an alloy including an alkali metal, a transition metal and an oxygen atom.

In addition, the alkali metal may comprise at least one selected from the group consisting of lithium (Li), sodium (Na), potassium (K), rubidium (Rb) and cesium (Cs).

In addition, the transition metal may comprise at least one selected from the group consisting of chromium (Cr), molybdenum (Mo) and tungsten (W).

In addition, the two-dimensional chalcogenide of the thin film may comprise at least one selected from the group consisting of chromium (Cr), molybdenum (Mo), and tungsten (W); and at least one selected from the group consisting of sulfur(S), selenium (Se) and tellurium (Te).

In addition, the liquid-phase alloy catalyst may be in a liquid phase at 500 to 900° C.

In addition, the liquid-phase alloy catalyst may act as a liquid-phase reaction intermediate to control a defect in a grain boundary of the thin film when forming the thin film using a vapor-liquid-solid synthesis method (VLS).

Another aspect of the present disclosure provides a method of manufacturing a liquid-phase alloy catalyst for synthesizing a two-dimensional chalcogenide thin film, the method comprising: (a) providing a glass substrate comprising an alkali metal and an oxygen atom; and (b) contacting the glass substrate with a gas-phase transition metal precursor, thus synthesizing a liquid-phase alloy catalyst comprising an alkali metal, a transition metal and an oxygen atom on the glass substrate.

In addition, the alkali metal may comprise at least one selected from the group consisting of lithium (Li), sodium (Na), potassium (K), rubidium (Rb) and cesium (Cs).

In addition, the transition metal may comprise at least one selected from the group consisting of chromium (Cr), molybdenum (Mo) and tungsten (W).

In addition, the two-dimensional chalcogenide of the thin film may comprise: at least one selected from the group consisting of chromium (Cr), molybdenum (Mo) and tungsten (W); and at least one selected from the group consisting of sulfur (S), selenium (Se) and tellurium (Te).

In addition, the step (b) may be carried out at a temperature in a range of 500 to 900° C.

Another aspect of the present disclosure provides a method of manufacturing a liquid-phase alloy catalyst for synthesizing a two-dimensional chalcogenide thin film, the method comprising: (a′) applying a solution comprising a compound including an alkali metal, a transition metal and an oxygen atom on a substrate and drying it, thus preparing a substrate on which the compound is coated; and (b′) heating the substrate coated with the compound to produce a liquid-phase alloy catalyst comprising an alkali metal, a transition metal and an oxygen atom in a liquid phase.

Another aspect of the present disclosure provides a method of manufacturing a two-dimensional chalcogenide thin film, the method comprising: (1) synthesizing a liquid-phase alloy catalyst comprising an alkali metal, a transition metal and oxygen atom; and (2) contacting the liquid-phase alloy catalyst with a gas-phase chalcogen precursor, thus preparing a thin film including a two-dimensional chalcogenide comprising a transition metal and a chalcogen element.

In addition, the liquid-phase alloy catalyst may provide a uniform concentration environment of the transition metal when forming the two-dimensional chalcogenide thin film.

In addition, the liquid-phase alloy catalyst may control a defect in a grain boundary of a two-dimensional chalcogenide crystal in the thin film when forming the two-dimensional chalcogenide thin film.

In addition, the step (2) may be carried out by a vapor-liquid-solid (VLS) synthesis method, and the liquid-phase alloy catalyst may act as a reaction intermediate to control the defect in the grain boundary.

In addition, the step (2) may be carried out at a temperature in a range of 500 to 900° C.

In addition, the step (2) may comprise: (2-1) contacting a chalcogen precursor with the liquid-phase alloy catalyst so that the chalcogen element is dissolved in the liquid-phase alloy catalyst; and precipitating (2-2) the two-dimensional chalcogenide comprising the transition metal and the chalcogen element from the liquid-phase alloy catalyst in which the chalcogen element is dissolved, thus preparing the two-dimensional chalcogenide thin film.

In addition, the liquid-phase alloy catalyst may be solidified and located in the grain boundary of the two-dimensional chalcogenide.

In addition, the alkali metal comprises at least one selected from the group consisting of lithium (Li), sodium (Na), potassium (K), rubidium (Rb) and cesium (Cs), the transition metal comprises at least one selected from the group consisting of chromium (Cr), molybdenum (Mo) and tungsten (W), and a chalcogen element of the gas-phase chalcogen precursor comprises at least one selected from the group consisting of sulfur (S), selenium (Se) and tellurium (Te).

In addition, the two-dimensional chalcogenide of the thin film may comprise at least one selected from the group consisting of MOS₂, WS₂, MoSe₂ and WSe₂.

The present disclosure has the effect of stably providing a uniform chemical environment through an independent liquid alloy catalyst in a chemically non-uniform synthetic environment.

In addition, by controlling the edge atoms of the crystal grains that have changed according to the local synthetic environment into one type, the grain boundary can also be controlled into one form with the same atomic structure in the present disclosure.

In addition, the present disclosure can bring about the effect of improving existing properties and expressing new properties.

In addition, by changing the elements that compose the liquid alloy catalyst, it is possible to create an alloy form with different components, thereby providing a chemically non-spontaneous, metastable environment in a stable and uniform form in the present disclosure.

In addition, the present disclosure can have the effect of being able to be used as an approach to synthesize substances that were previously difficult to synthesize and to inject additional impurities.

### BRIEF DESCRIPTION OF THE DRAWINGS

These drawings are for the purpose of describing exemplary embodiments of the present disclosure, and therefore the technical idea of the present disclosure should not be construed as being limited to the accompanying drawings:

FIG. 1A is a schematic diagram showing a catalyst for forming a two-dimensional chalcogenide thin film of the present disclosure and a thin film formed using the catalyst according to Example 1.

FIG. 1B is the results of confirming the structure in which a liquid-phase alloy catalyst is solidified at the boundary of a two-dimensional semiconductor material grown after the completion of synthesis using a transmission electron microscope.

FIG. 1C is an EDS image confirming that the components of the structure in which a liquid-phase alloy catalyst is solidified at the boundary of a two-dimensional semiconductor material grown after the completion of synthesis are composed of Na, Mo, O, and S.

FIG. 1D shows the process of synthesizing a WSe₂-thin film of Example 4 in the present disclosure.

FIG. 1E is an optical image of a WSe₂ thin film of Example 4 in the present disclosure.

FIG. 1F is a Raman spectra and emission spectra for the synthesis of a monolayer WSe₂ thin film of Example 4 in the present disclosure.

FIG. 2A shows a comparison between the vapor-solid-solid synthesis method (Vapor-Solid-Solid, VSS), which is a general chemical vapor deposition mechanism of Comparative Example, and the vapor-liquid-solid synthesis method (Vapor-Liquid-Solid, VLS), which uses the liquid-phase alloy catalyst of Example 1 of the present disclosure as a reaction intermediate.

FIG. 2B is an electron transmission microscope image comparing the macroscopic grain boundary shapes at the same degree of twist) (˜20° for the VSS synthesis method, which is a comparative example, and the VLS synthesis method of Example 1 of the present disclosure.

FIG. 2C is the grain boundary shapes when magnified to the atomic level for the VSS synthesis method, which is a comparative example.

FIG. 2D is the grain boundary shapes when magnified to the atomic level for the VLS synthesis method of Example 1 of the present disclosure.

FIG. 3A shows a consecutive VLS and VSS growth for direct comparison of each grain boundaries (GB) with a similar θₜ, inset is STEM atomic images for edges grown by each growth mode, which of scale bar is 0.5 nm.

FIG. 3B is photoluminescence (PL) intensity mapping image for the resultant sample grown by the method shown in FIG. 3A, and scale bar is 5 μm.

FIG. 3C is PL intensity mapping image for VLS-GB (the region indicated by the ⋄ symbol) and VSS-GBs (the region indicated by the ∇ symbol) with an excitation energy of 1.88 eV and incident power density of ˜5×10³ W/cm² and scale bar is 1 μm. FIG. 3D is PL spectra corresponding to FIG. 3C.

### DESCRIPTION OF THE PREFERRED EMBODIMENTS

Herein after, embodiments of the present disclosure will be described in detail with reference to the accompanying drawings in such a manner that the ordinarily skilled in the art can easily implement the embodiments of the present disclosure.

The description given below is not intended to limit the present disclosure to specific Examples. In relation to describing the present disclosure, when the detailed description of the relevant known technology is determined to unnecessarily obscure the gist of the present disclosure, the detailed description may be omitted.

The terminology used herein is for the purpose of describing particular examples only and is not intended to limit the scope of the present disclosure. As used herein, the singular forms “a”, “an”, and “the” are intended to comprise the plural forms as well unless the context clearly indicates otherwise. It will be further understood that the terms “comprise” or “have” when used in the present disclosure specify the presence of stated features, integers, steps, operations, elements and/or combinations thereof, but do not preclude the presence or addition of one or more other features, integers, steps, operations, elements, and/or combinations thereof.

Terms comprising ordinal numbers used in the specification, “first”, “second”, etc. can be used to discriminate one component from another component, but the order or priority of the components is not limited by the terms unless specifically stated.

These terms are used only for the purpose of distinguishing a component from another component. For example, without departing from the scope of the present disclosure, a first component may be referred as a second component, and a second component may be also referred to as a first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, a liquid-phase alloy catalyst, method of manufacturing same and two-dimensional chalcogenide thin film comprising thermodynamically induced grain boundary in monolayer crystal using same, according to the present disclosure, will be described in detail. However, those are described as examples, and the present invention is not limited thereto and is only defined by the scope of the appended claims.

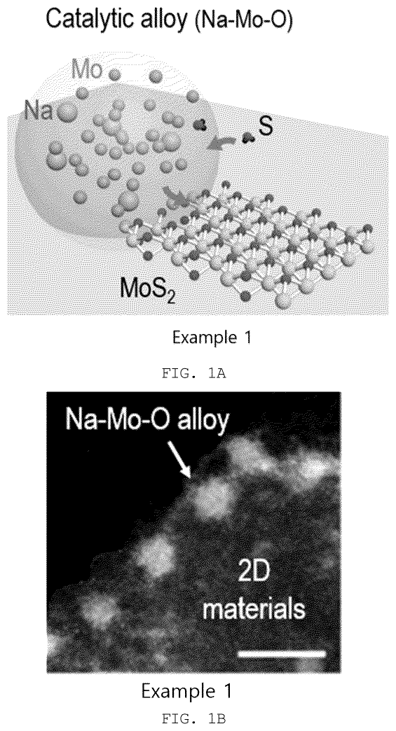

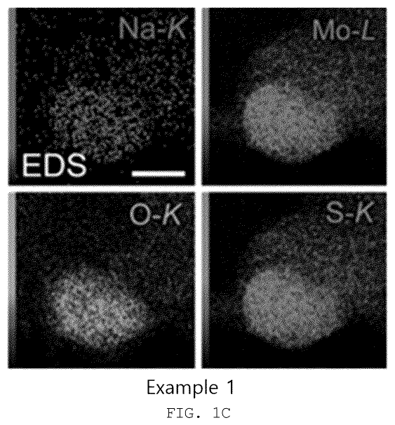

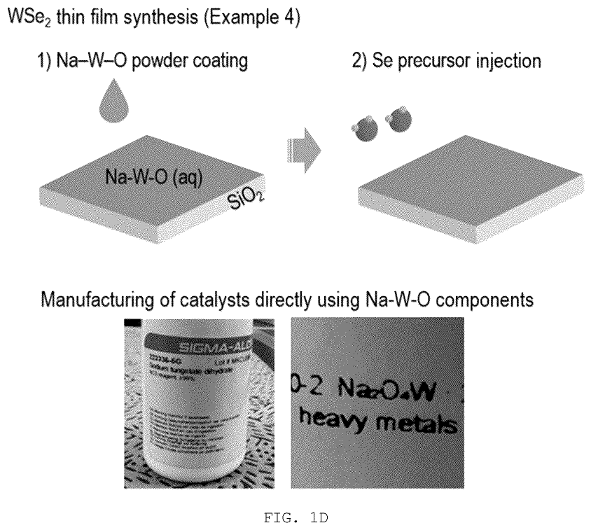

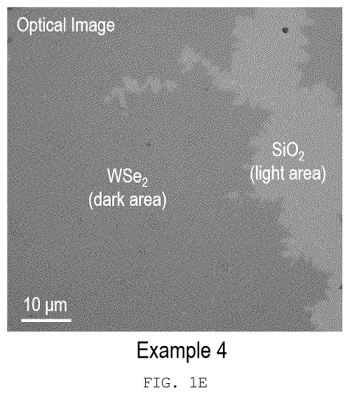

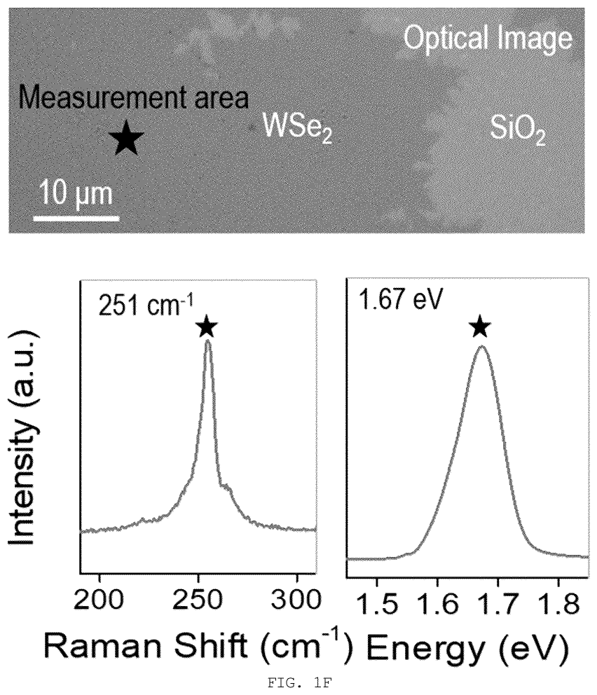

FIG. 1A is a schematic diagram showing a catalyst for forming a two-dimensional chalcogenide thin film of the present disclosure and a thin film formed using the catalyst according to Example 1.

Referring to FIG. 1A, one aspect of the present disclosure provides a liquid-phase alloy catalyst for synthesizing a two-dimensional chalcogenide thin film, the liquid-phase alloy catalyst comprising an alloy including an alkali metal, transition metal and an oxygen atom.

In addition, the alkali metal may comprise at least one selected from the group consisting of lithium (Li), sodium (Na), potassium (K), rubidium (Rb) and cesium (Cs).

In addition, the transition metal may comprise at least one selected from the group consisting of chromium (Cr), molybdenum (Mo) and tungsten (W), preferably at least one selected from the group consisting of molybdenum (Mo) and tungsten (W).

In addition, the two-dimensional chalcogenide of the thin film may comprise at least one selected from the group consisting of chromium (Cr), molybdenum (Mo), and tungsten (W); and at least one selected from the group consisting of sulfur (S), selenium (Se) and tellurium (Te).

In addition, the liquid-phase alloy catalyst may be in a liquid phase at 500 to 900° C.

In addition, the liquid-phase alloy catalyst may act as a liquid-phase reaction intermediate to control a defect in a grain boundary of the thin film when forming the thin film using a vapor-liquid-solid synthesis method (VLS).

Another aspect of the present disclosure provides a method of manufacturing a liquid-phase alloy catalyst for synthesizing a two-dimensional chalcogenide thin film, the method comprising: (a) providing a glass substrate comprising an alkali metal and an oxygen atom; and (b) contacting the glass substrate with a gas-phase transition metal precursor, thus synthesizing a liquid-phase alloy catalyst comprising an alkali metal, a transition metal and an oxygen atom on the glass substrate.

In addition, the alkali metal may comprise at least one selected from the group consisting of lithium (Li), sodium (Na), potassium (K), rubidium (Rb) and cesium (Cs).

In addition, the transition metal may comprise at least one selected from the group consisting of chromium (Cr), molybdenum (Mo) and tungsten (W).

In addition, the two-dimensional chalcogenide of the thin film may comprise: at least one selected from the group consisting of chromium (Cr), molybdenum (Mo) and tungsten (W); and at least one selected from the group consisting of sulfur(S), selenium (Se) and tellurium (Te).

In addition, the step (b) may be carried out at a temperature in a range of 500 to 900° C. When the temperature of the step (b) is lower than 500° C., it is undesirable due to the difficulty in maintaining the liquid-phase of the catalyst and the very low solubility condition. When V it higher than 900° C., it is undesirable due to the difficulty in nucleation caused by vaporization of the liquid-phase catalyst.

Another aspect of the present disclosure provides a method of manufacturing a liquid-phase alloy catalyst for synthesizing a two-dimensional chalcogenide thin film, the method comprising: (a′) applying a solution comprising a compound including an alkali metal, a transition metal and an oxygen atom on a substrate and drying it, thus preparing a substrate on which the compound is coated; and (b′) heating the substrate coated with the compound to produce a liquid-phase alloy catalyst comprising an alkali metal, a transition metal and an oxygen atom in a liquid phase.

Another aspect of the present disclosure provides a method of manufacturing a two-dimensional chalcogenide thin film, the method comprising: (1) synthesizing a liquid-phase alloy catalyst comprising an alkali metal, a transition metal and oxygen atom; and (2) contacting the liquid-phase alloy catalyst with a gas-phase chalcogen precursor, thus preparing a thin film including a two-dimensional chalcogenide comprising a transition metal and a chalcogen element.

In addition, the liquid-phase alloy catalyst may provide a uniform concentration environment of the transition metal when forming the two-dimensional chalcogenide thin film.

In addition, the liquid-phase alloy catalyst may control a defect in a grain boundary of a two-dimensional chalcogenide crystal in the thin film when forming the two-dimensional chalcogenide thin film.

In addition, the step (2) may be carried out by a vapor-liquid-solid (VLS) synthesis method, and the liquid-phase alloy catalyst may act as a reaction intermediate to control the defect in the grain boundary.

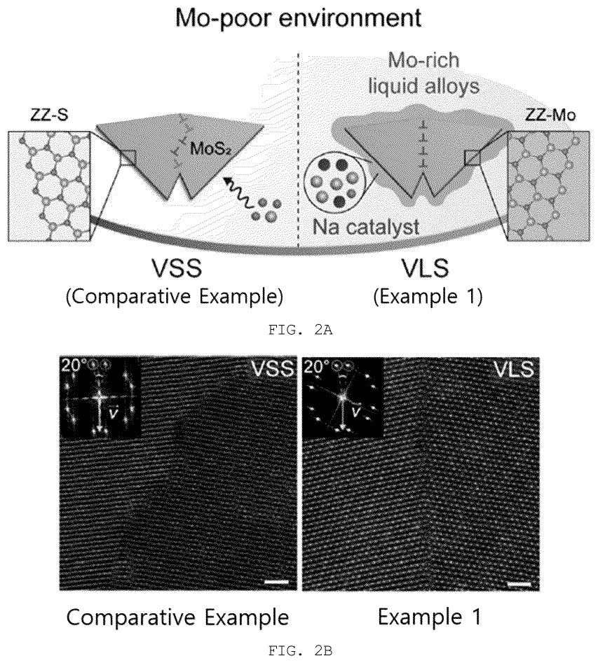

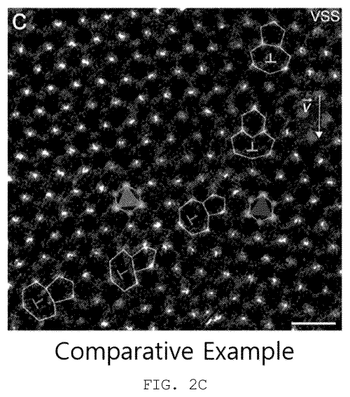

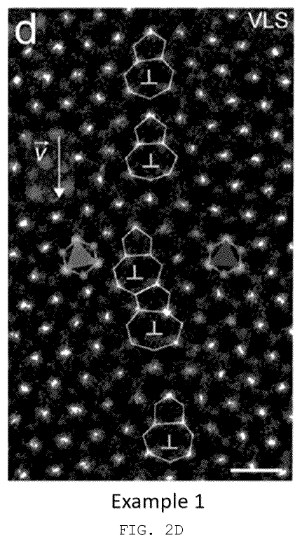

FIG. 2A shows a comparison between the vapor-solid-solid synthesis method (Vapor-Solid-Solid, VSS), which is a general chemical vapor deposition mechanism, and the vapor-liquid-solid synthesis method (Vapor-Liquid-Solid, VLS), which uses the liquid-phase alloy catalyst of the present disclosure as a reaction intermediate.

Referring to FIG. 2A, the present disclosure may provide a two-dimensional chalcogenide thin film including grain boundary with controlled defect using the alloy catalyst.

In addition, the liquid-phase alloy catalyst may be solidified and located in the grain boundary of the two-dimensional chalcogenide.

In addition, the defect may be controlled in the same manner.

In addition, the thin film can grow through a process in which the chalcogen element is dissolved and precipitated when the thin film is formed.

In addition, the step (2) may be carried out at a temperature in a range of 500 to 900° C. When the temperature of the step (2) is lower than 500° C., it is undesirable due to the difficulty in maintaining the liquid-phase of the catalyst and the very low solubility condition. When it is higher than 900° C., it is undesirable due to the difficulty in nucleation caused by vaporization of the liquid-phase catalyst.

In addition, the step (2) may comprise: (2-1) contacting a chalcogen precursor with the liquid-phase alloy catalyst so that the chalcogen element is dissolved in the liquid-phase alloy catalyst; and (2-2) precipitating the two-dimensional chalcogenide comprising the transition metal and the chalcogen element from the liquid-phase alloy catalyst in which the chalcogen element is dissolved, thus preparing the two-dimensional chalcogenide thin film.

In addition, the liquid-phase alloy catalyst may be solidified and located in the grain boundary of the two-dimensional chalcogenide.

In addition, the alkali metal comprises at least one selected from the group consisting of lithium (Li), sodium (Na), potassium (K), rubidium (Rb) and cesium (Cs), the transition metal comprises at least one selected from the group consisting of chromium (Cr), molybdenum (Mo) and tungsten (W), and a chalcogen element of the gas-phase chalcogen precursor comprises at least one selected from the group consisting of sulfur (S), selenium (Se) and tellurium (Te).

In addition, the two-dimensional chalcogenide of the thin film may comprise at least one selected from the group consisting of MOS₂, WS₂, MoSe₂ and WSe₂.

According to another aspect of the present disclosure provides a chemical synthesis environment control system utilizing the catalyst.

The present disclosure utilizes behavior based on thermodynamic mechanisms for the first problem presented as a problem of the prior art. Theoretically, the atomic structure constituting the grain boundary is formed in one thermodynamically stable form, and the prerequisite for this is that it must grow through a uniform chemical environment. If a liquid-phase alloy having an independent phase from the non-uniform chemical environment of the vapor precursor within the existing chemical vapor deposition method is formed as a reaction intermediate, it can have the effect of additionally creating a chemically uniform reactor. As a result, it is expected that the grain boundary is formed only in one atomic structure that is the most thermodynamically stable in the environment. For the second problem, by adding an alkali metal that can have a catalytic effect on the existing two-dimensional material synthesis to the liquid-phase alloy introduced as a reaction intermediate, thin film synthesis can be possible even at a relatively low temperature (500° C.). In addition, if a liquid-phase alloy is produced with various transition metals, it is expected that it will provide an environment in which new material synthesis is possible by uniformly providing a metastable chemical environment for the problem of the newly proposed new material production perspective.

The properties of polycrystalline thin films can be controlled by defects existing in grain boundaries. It is known that the defect structure existing in grain boundaries is controlled by the chemical environment existing during synthesis, but it is difficult to control the vapor environment, and in actual chemical vapor deposition, grain boundaries with various types of defects are formed through a dynamic mechanism.

Therefore, the present disclosure introduced a liquid-phase alloy catalyst of Na, Mo, and O components as a reaction intermediate to induce a vapor-liquid-solid synthesis method (VLS) that is different from the existing chemical vapor deposition method. The liquid-phase alloy catalyst can control the chemical environment that was difficult to control in the existing vapor phase by creating an isolated liquid phase. Controlled grain boundaries showed higher luminescence characteristics than grain interiors and uncontrolled grain boundaries through a single atomic structure, and this disclosure confirmed that defect control at grain boundaries can control the properties of polycrystalline films. Unlike existing synthesis methods, the VLS synthesis method using a liquid-phase alloy catalyst (Na—Mo—O) can control one type of grain boundary by providing a Mo-rich environment.

The present disclosure can be used in polycrystalline thin film synthesis technology requiring grain boundary control and the field of property control through grain boundaries, low-temperature processes through catalytic effects, and new material synthesis technology through providing a chemical environment that was difficult to form.

In addition, when synthesizing a two-dimensional material (such as MoS₂) polycrystalline thin film, it can be controlled in the form of grain boundaries with defects consisting of the same atomic structure.

In addition, as an application field, thin film synthesis of the present disclosure can be implemented at relatively low temperatures through the catalytic effect, and materials that were previously difficult to synthesize can be approached.

In addition, it can be applied to various thin film synthesis processes that can introduce the liquid-phase catalytic alloy of the present disclosure, such as a two-dimensional polycrystalline thin film synthesis method using chemical vapor deposition.

### EXAMPLES

Hereinafter, the examples of the present disclosure will be described. However, the examples are for illustrative purposes, and the scope of the present disclosure is not limited by the examples.

### Preparation Example: Preparation of Liquid-Phase Alloy Catalyst

### Preparation Example 1: Na—Mo—O Liquid-Phase Alloy Catalyst

Molybdenum Hexacarbonyl, [Mo(CO)₆] which is a gas-phase Mo precursor, was applied onto a glass substrate containing sodium atom (Na) and oxygen atom (O) at 600° C. to form a liquid-phase alloy catalyst comprising Na, Mo, and O components at the process temperature.

### Preparation Example 2: Na—W—O Liquid-Phase Alloy Catalyst

A solution of sodium tungstate dihydrate (Na₂O₄W(H₂O)₂) containing Na, W, and O was applied onto a silica (SiO₂) substrate and dried to prepare a silica substrate coated with sodium tungstate dihydrate. The silica substrate coated with sodium tungstate dihydrate was heated to 600° C. to form a liquid-phase alloy catalyst containing Na, W, and O components.

### Example: Preparation of Thin Films Using VLS Synthesis

### Example 1: Preparation of MoS₂ Two-Dimensional Chalcogenide Thin Film

A monolayer MoS₂ thin film was prepared using the vapor-liquid-solid (VLS) synthesis method using the Na—Mo—O liquid-phase alloy catalyst of Preparation Example 1 of the present disclosure as a reaction intermediate. Molybdenum Hexacarbonyl, [Mo(CO)₆] which are a vapor phase Mo precursor, were applied onto a glass substrate containing sodium atom (Na) and oxygen atom (O) at 600° C. to form an intermediate sodium molibdate (Na—Mo—O), a liquid-phase alloy catalyst containing Na, Mo, and O components. Diethyl Sulfide and [(C₂H₅)₂S], which is a vapor phase sulfur precursor, were applied, and S atom was dissolved and precipitated in the form of MoS₂, thereby fabricating a monolayer MoS₂ thin film.

### Example 2: Preparation of MoSe₂ Two-Dimensional Chalcogenide Thin Film

A monolayer MoSe₂ thin film was prepared using the vapor-liquid-solid synthesis method (VLS) using the Na—Mo—O liquid-phase alloy catalyst of Preparation Example 1 of the present disclosure as a reaction intermediate. Molybdenum Hexacarbonyl and [Mo(CO)₆] which are a vapor phase Mo precursor, were applied onto a glass substrate containing sodium atom (Na) and oxygen atom (O) at 600° C. to form an intermediate sodium molybdate (Na—Mo—O) of a liquid-phase alloy catalyst containing Na, Mo, and O components. Dimethyl Selenide and [(CH₃)₂Se] which is a vapor phase selenium (Se) precursor, were applied, and Se atom was dissolved and precipitated in the form of MoSe₂, thereby fabricating a monolayer MoSe₂ thin film.

### Example 3: Preparation of a WS₂ Two-Dimensional Chalcogenide Thin Film

Referring to FIGS. 1D to 1F, an aqueous solution of sodium tungstate dihydrate (Na₂O₄W(H₂O)₂) containing Na, W, and O was applied onto a silica (SiO₂) substrate and dried to prepare a silica substrate coated with sodium tungstate dihydrate. Diethyl Sulfide, [(C₂H₅)₂S] which are a gas-phase S precursor, were applied onto the silica substrate coated with sodium tungstate dihydrate at 600° C. to form a liquid-phase alloy catalyst containing intermediate Na, W, and O components at the process temperature and S was dissolved and precipitated in the form of WS₂, thereby fabricating a two-dimensional WS₂ thin film as a monolayer.

### Example 4: Preparation of WSe₂ Two-Dimensional Chalcogenide Thin Film

Referring to FIGS. 1D to 1F, an aqueous solution of sodium tungstate dihydrate, (Na₂O₄W(H₂O)₂) containing Na, W, and O was applied onto a silica (SiO₂) substrate and dried to prepare a silica substrate coated with sodium tungstate dihydrate. Dimethyl Selenide, [(CH₃)₂Se] which are gas-phase Se precursor, were applied onto the silica substrate coated with sodium tungstate dihydrate at 600° C. to form a liquid-phase alloy catalyst containing intermediate Na, W, and O components at the process temperature, and Se was dissolved and precipitated in the form of WSe₂, thereby fabricating a WSe₂ thin film as a monolayer.

### Comparative Example: Preparation of MoS₂ Thin Films Using VSS Synthesis Method

MoS₂ two-dimensional chalcogenide thin film fabrication was grown using the vapor-solid-solid synthesis method (VSS), which is a general chemical vapor deposition mechanism. MoS₂ two-dimensional chalcogenide thin film was grown by applying the synthesis condition of reaction temperature 600° C. to the substrate (quartz glass, thermal SiO₂, etc.) that does not contain alkali metal substances, using Molybdenum Hexacarbonyl, [Mo(CO)₆] as a vapor phase Mo precursor, and Diethyl Sulfide, [(C₂H₅)₂S] as a vapor phase S precursor.

Table 1 below summarizes the chemical vapor deposition method and two-dimensional chalcogenide thin films according to Comparative Example and Examples 1 to 4 of the present disclosure.

TABLE 1

| | chemical vapor | two-dimensional |
|---|---|---|
| Classification | deposition method | chalcogenide thin film |
| Example 1 | Vapor-Liquid-Solid, VLS | MOS₂ |
| Example 2 | | MoSe₂ |
| Example 3 | | WS₂ |
| Example 4 | | WSe₂ |
| Comparative | Vapor-Solid-Solid, VSS | MOS₂ |
| Example | | |

### TEST EXAMPLE

### Test Example 1: Analysis of Liquid-Phase Alloy Catalysts and Two-Dimensional Chalcogenide Thin Films (Transmission Electron Microscopy and EDS Analysis)

### Test Example 1-1: Confirmation of MoS₂ Thin Film Synthesis

FIG. 1A is a schematic diagram showing a catalyst for forming a two-dimensional chalcogenide thin film of the present disclosure and a thin film formed using the catalyst according to Example 1, FIG. 1B is the results of confirming the structure in which a liquid-phase alloy catalyst is solidified at the boundary of a two-dimensional semiconductor material grown after the completion of synthesis using transmission electron microscope and FIG. 1C is an EDS image confirming that the components of the structure in which a liquid-phase alloy catalyst is solidified at the boundary of a two-dimensional semiconductor material grown after the completion of synthesis are composed of Na, Mo, O, and S.

Referring to FIGS. 1A to 1C, when a Mo vapor precursor was applied onto a glass substrate containing sodium atom (Na) and oxygen atom (O) during the synthesis of MoS₂, a two-dimensional semiconductor material, it was expected that a liquid-phase alloy catalyst of Na, Mo, and O components would be formed at the process temperature (˜600° C.). Another reactant, S, dissolved in the formed Na—Mo—O liquid-phase alloy catalyst and precipitated in the form of MoS₂, which was then grown.

After the synthesis was completed, the solidified structure of the liquid-phase alloy catalyst at the boundary of the grown two-dimensional semiconductor material was confirmed through a transmission electron microscope. And thus its constituent components were confirmed to be composed of Na, Mo, O, and S. Through this, it was confirmed that a uniform chemical environment rich in Mo can be provided through the liquid-phase alloy catalyst.

### Test Example 1-2: Confirmation of WSe₂ Thin Film Synthesis

FIG. 1D shows the process of synthesizing a WSe₂-thin film of Example 4 of the present disclosure, FIG. 1E is an optical image of a WSe₂ thin film of Example 4 of the present disclosure and FIG. 1F is a Raman spectra and emission spectra for the synthesis of a monolayer WSe₂ thin film of Example 4 of the present disclosure.

Referring to FIGS. 1D to 1F, the powder of the Na—W—O component was purchased and applied onto the surface in advance so that it could act as a catalyst. When the Raman spectroscopy and emission characteristics of the synthesized thin film were confirmed, the Raman spectrum (251) and emission spectrum (1.67) characteristic of a monolayer WSe₂ were almost identical to the generally known reference values (Raman spectrum 251, emission spectrum 1.65), confirming that it was formed as a monolayer thin film.

### Test Example 2: Analysis of Defect Control of Grain Boundary (SEM Analysis and EDS Mapping)

FIG. 2A shows a comparison between the vapor-solid-solid synthesis method (Vapor-Solid-Solid, VSS), which is a general chemical vapor deposition mechanism of Comparative Example, and the vapor-liquid-solid synthesis method (Vapor-Liquid-Solid, VLS), which uses the liquid-phase alloy catalyst of Example 1 of the present disclosure as a reaction intermediate, FIG. 2B is an electron transmission microscope image comparing the macroscopic grain boundary shapes at the same degree of twist) (˜20° for the VSS synthesis method, which is a comparative example, and the VLS synthesis method of Example 1 of the present disclosure, FIG. 2C is the grain boundary shapes when magnified to the atomic level for the VSS synthesis method, which is a comparative example and FIG. 2D is the grain boundary shapes when magnified to the atomic level for the VLS synthesis method of Example 1 of the present disclosure.

Referring to FIGS. 2A to 2D, when comparing the vapor-solid-solid synthesis method (Vapor-Solid-Solid, VSS) which is a general chemical vapor deposition mechanism with the vapor-liquid-solid synthesis method (Vapor-Liquid-Solid, VLS) which used liquid-phase alloy catalyst that the inventors introduced as a reaction intermediate, the macroscopic shapes of the grain boundaries were different, as shown in the transmission electron microscope image, even though they had the same degree of twist) (˜20°.

In addition, when this was magnified to the atomic level, VSS synthesis method which has a chemical environment in the form of a gas phase formed grain boundaries through different defects. And thus it was confirmed that the macroscopic grain boundaries were not in a straight line shape. In contrast, the grain boundary synthesized through VLS was composed of one type of defect, and thus the macroscopic grain boundary also appeared in a straight line shape.

### Test Example 3: Evaluation of Luminescence Characteristics of Controlled Grain Boundary

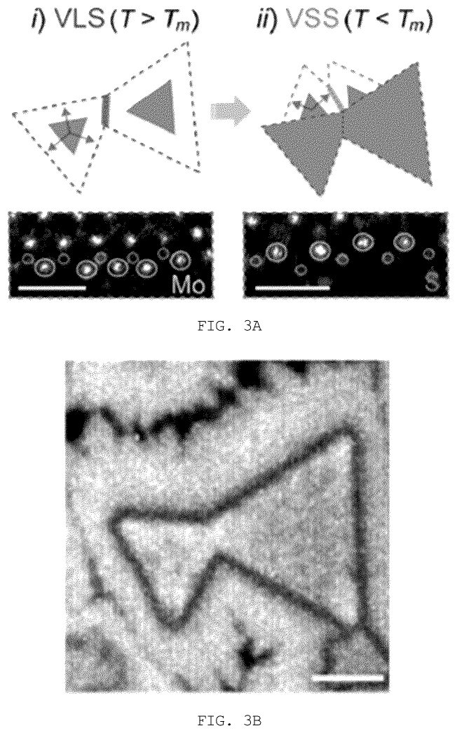

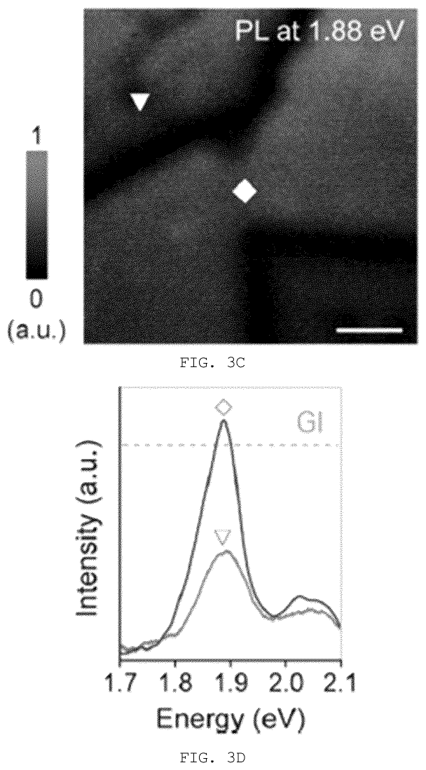

FIG. 3A shows an consecutive VLS and VSS growth for direct comparison of each grain boundaries (GB) with a similar θₜ, inset is STEM atomic images for edges grown by each growth mode, which of scale bar is 0.5 nm, FIG. 3B is photoluminescence (PL) intensity mapping image for the resultant sample grown by the method shown in FIG. 3A, and scale bar is 5 μm, FIG. 3C is PL intensity mapping image for VLS-GB (the region indicated by the ⋄ symbol) and VSS-GBs (the region indicated by the ∇ symbol) with an excitation energy of 1.88 eV and incident power density of ˜5×10³ W/cm² and scale bar is 1 μm and FIG. 3D is PL spectra corresponding to FIG. 3C.

Referring to FIG. 3A to 3D, in order to directly compare the change in the properties of grain boundary controlled by VSS and VLS synthesis methods, grain boundary of different shapes was formed by controlling the presence or absence of a liquid-phase alloy catalyst in one specimen through temperature control. As a result of confirming the luminescence characteristics for each grain boundary, it was confirmed that the VLS grain boundary formed in one shape showed luminescence characteristics similar to or higher than the interior of a defect-free grain, and in particular, it showed luminescence characteristics with higher efficiency than the grain boundaries formed by VSS.

The scope of the present disclosure is defined by the following claims rather than the above detailed description, and all changes or modifications derived from the meaning and scope of the claims and their equivalent concepts should be interpreted as falling into the scope of the present disclosure.

What is claimed is:

1. A liquid-phase alloy catalyst for synthesizing a two-dimensional chalcogenide thin film, the liquid-phase alloy catalyst comprising an alloy including an alkali metal, a transition metal and an oxygen atom.

2. The liquid-phase alloy catalyst of claim 1, wherein the alkali metal comprises at least one selected from the group consisting of lithium (Li), sodium (Na), potassium (K), rubidium (Rb) and cesium (Cs).

3. The liquid-phase alloy catalyst of claim 1, wherein the transition metal comprises at least one selected from the group consisting of chromium (Cr), molybdenum (Mo) and tungsten (W).

4. The liquid-phase alloy catalyst of claim 1, wherein a two-dimensional chalcogenide of the thin film comprises:
at least one selected from the group consisting of chromium (Cr), molybdenum (Mo), and tungsten (W); and
at least one selected from the group consisting of sulfur (S), selenium (Se) and tellurium (Te).

5. The liquid-phase alloy catalyst of claim 1, wherein the liquid-phase alloy catalyst is in a liquid phase at 500 to 900° C.

6. The liquid-phase alloy catalyst of claim 5, wherein the liquid-phase alloy catalyst acts as a liquid-phase reaction intermediate to control a defect in a grain boundary of the thin film when forming the thin film using a vapor-liquid-solid synthesis method (VLS).

7. A method of manufacturing a liquid-phase alloy catalyst for synthesizing a two-dimensional chalcogenide thin film, the method comprising:
(a) providing a glass substrate comprising an alkali metal and an oxygen atom; and
(b) contacting the glass s substrate with a gas-phase transition metal precursor, thus synthesizing a liquid-phase alloy catalyst comprising an alkali metal, a transition metal and an oxygen atom on the glass substrate.

8. The method of claim 7, wherein the alkali metal comprises at least one selected from the group consisting of lithium (Li), sodium (Na), potassium (K), rubidium (Rb) and cesium (Cs).

9. The method of claim 7, wherein the transition metal comprises at least one selected from the group consisting of chromium (Cr), molybdenum (Mo) and tungsten (W).

10. A method of claim 7, wherein the two-dimensional chalcogenide of the thin film comprises:
at least one selected from the group consisting of chromium (Cr), molybdenum (Mo) and tungsten (W); and
at least one selected from the group consisting of sulfur (S), selenium (Se) and tellurium (Te).

11. The method of claim 7, wherein the step (b) is carried out at a temperature in a range of 500 to 900° C.

12. A method of manufacturing a two-dimensional chalcogenide thin film, the method comprising:
(1) synthesizing a liquid-phase alloy catalyst comprising an alkali metal, a transition metal and oxygen atom; and
(2) contacting the liquid-phase alloy catalyst with a gas-phase chalcogen precursor, thus preparing a thin film including a two-dimensional chalcogenide comprising a transition metal and a chalcogen element.

13. The method of claim 12, wherein the liquid-phase alloy catalyst provides a uniform concentration environment of the transition metal when forming the two-dimensional chalcogenide thin film.

14. The method of claim 12, wherein the liquid-phase alloy catalyst controls a defect in a grain boundary of a two-dimensional chalcogenide crystal in the thin film when forming the two-dimensional chalcogenide thin film.

15. The method of claim 14, wherein the step (2) is carried out by a vapor-liquid-solid (VLS) synthesis method, and
the liquid-phase alloy catalyst acts as a reaction intermediate to control the defect in the grain boundary.

16. The method of claim 12, wherein the step (2) is carried out at a temperature in a range of 500 to 900° C.

17. The method of claim 12, the step (2) comprises:
(2-1) contacting a chalcogen precursor with the liquid-phase alloy catalyst so that the chalcogen element is dissolved in the liquid-phase alloy catalyst; and
(2-2) precipitating the two-dimensional chalcogenide comprising the transition metal and the chalcogen element from the liquid-phase alloy catalyst in which the chalcogen element is dissolved, thus preparing the two-dimensional chalcogenide thin film.

18. The method of claim 12, wherein the liquid-phase alloy catalyst is solidified and located in the grain boundary of the two-dimensional chalcogenide.

19. The method of claim 12, wherein the alkali metal comprises at least one selected from the group consisting of lithium (Li), sodium (Na), potassium (K), rubidium (Rb) and cesium (Cs),
the transition metal comprises at least one selected from the group consisting of chromium (Cr), molybdenum (Mo) and tungsten (W), and
a chalcogen element of the gas-phase chalcogen precursor comprises at least one selected from the group consisting of sulfur (S), selenium (Se) and tellurium (Te).

20. The method of claim 12, wherein the two-dimensional chalcogenide of the thin film comprises at least one selected from the group consisting of MoS₂, WS₂, MoSe₂ and WSe₂.
